(19) United States
(12) Patent Application Publication
(10) Pub. No.: US 2010/0065898 A1
(43) Pub. Date: Mar. 18, 2010

(54) Integrated circuit semiconductor device having different gate stacks in cell region and core/peripheral region and method of manufacturing the same

(76) Inventors: Young-jin Choi, Hwaseong-si (KR); Kang-ill Seo, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 12/458,438

(22) Filed: Jul. 13, 2009

(30) Foreign Application Priority Data
Sep. 16, 2008 (KR) 10-2008-0090685

(51) Int. Cl. H01L 27/108; H01L 21/8242

(52) U.S. Cl. 257/296; 438/591; 257/E27.084; 257/E21.646; 257/E21.409

(57) ABSTRACT

The integrated circuit semiconductor device includes a semiconductor substrate having a cell region and a core/peripheral region, a first gate stack including a first gate insulating film and a first gate electrode on the semiconductor substrate in the cell region, wherein the first gate insulating film includes a silicon oxide film and the first gate electrode includes a poly-silicon film doped with impurities, and a second gate stack including a second gate insulating film and a second gate electrode on the semiconductor substrate of the core/peripheral region, the second gate insulating film includes a high dielectric film having a higher dielectric constant than that of the silicon oxide film and the second gate electrode includes a metal film.

### BACKGROUND

1. Field

Embodiments relate to an integrated circuit semiconductor device and a method of manufacturing the integrated circuit semiconductor device and, more particularly, to an integrated circuit semiconductor device having different gate stacks in a cell region and in a core/peripheral region and a method of manufacturing the integrated circuit semiconductor device.

2. Description of the Related Art

While high efficiency and high integration are being accomplished in integrated circuit semiconductor devices, it is also important that the integrated circuit semiconductor devices be operated with a low power. High efficiency and high integration are also being accomplished in a MOS transistor, which is one of the elements forming the integrated circuit semiconductor device. The MOS transistors included in the integrated circuit semiconductor device are mainly formed in a cell region and in a core/peripheral region. The cell region is where a memory or a non-memory MOS transistor is formed. The MOS transistors in the core/peripheral region are formed to drive the MOS transistors in the cell region. The peripheral region may be also referred to as a peripheral circuit region.

### SUMMARY

Embodiments are therefore directed to an integrated circuit semiconductor device having different gate stacks in a cell region and core/peripheral region and to a method of manufacturing the same, which substantially overcome one or more of the problems due to the limitations and disadvantages of the related art.

It is therefore a feature of an embodiment to provide an integrated circuit semiconductor device having different gate stacks in a cell region and in a core/peripheral region for controlling efficiency of the integrated circuit semiconductor device in the cell region and in the core/peripheral region.

It is therefore another feature of an embodiment to provide a method of manufacturing an integrated circuit semiconductor device, the integrated circuit semiconductor device including different gate stacks in a cell region and in a core/peripheral region, wherein the cell region and the core/peripheral region are formed on a semiconductor substrate.

At least one of the above and other features and advantages may be realized by providing an integrated circuit semiconductor device including a semiconductor substrate having a cell region and a core/peripheral region, a first gate stack including a first gate insulating film and a first gate electrode on the semiconductor substrate in the cell region, wherein the first gate insulating film includes a silicon oxide film and the first gate electrode includes a poly-silicon film doped with impurities, and a second gate stack including a second gate insulating film and a second gate electrode on the semiconductor substrate of the core/peripheral region, wherein the second gate insulating film includes a high dielectric film having a higher dielectric constant than that of the silicon oxide film and the second gate electrode includes a metal film.

The integrated circuit semiconductor device may be a dynamic random access memory (DRAM) semiconductor device.

The device may further have a third gate stack including a third gate insulating film and a third gate electrode on the semiconductor substrate in the core/peripheral region, wherein the third gate insulating film includes a silicon oxide film and the third gate electrode includes a poly-silicon film doped with impurities.

The third gate insulating film may have a thickness that is substantially the same as a thickness of the first gate insulating film.

The second gate insulating film may include a silicon oxide film and the high dielectric film, and the high dielectric film may be on the silicon oxide film on the semiconductor substrate.

The second gate electrode may include a poly-silicon film and the metal film, and the poly-silicon film may be doped with impurities and is on the metal film.

At least one of the above and other features and advantages may also be realized by providing an integrated circuit semiconductor device including a semiconductor substrate having a cell region and a core/peripheral region, trenches in the semiconductor substrate in the cell region, a first gate stack in the cell region, the first gate stack including a silicon oxide film on inner walls and a bottom surface of the trenches and a poly-silicon film doped with impurities on the silicon oxide film in the trenches and projected above the semiconductor substrate, and a second gate stack in the core/peripheral region, the second gate stack sequentially including a silicon oxide film, a high dielectric film having a higher dielectric constant than that of the silicon oxide film, a metal film, and a poly-silicon film on the semiconductor substrate.

The device may further include a third gate stack including a silicon oxide film and a poly-silicon film on the semiconductor substrate in the core/peripheral region, wherein the poly-silicon film is doped with impurities.

The silicon oxide film of the third gate stack may have a thickness that is substantially the same as a thickness of the silicon oxide film of the first gate stack.

At least one of the above and other features and advantages may also be realized by providing a method of manufacturing an integrated circuit semiconductor device, the method includes providing a semiconductor substrate, sequentially forming a first silicon oxide film and a first poly-silicon film pattern doped with impurities on the semiconductor substrate in a cell region of the semiconductor substrate, sequentially forming a second silicon oxide film, a high dielectric film having a higher dielectric constant than that of the second silicon oxide film, a metal film, and a second poly-silicon film pattern on the semiconductor substrate in a core/peripheral region of the semiconductor substrate, forming a first gate stack including a first gate insulating film and a first gate electrode by patterning the first silicon oxide film and the first poly-silicon film pattern in the cell region, wherein the first gate insulating film includes a silicon oxide film and a first gate electrode includes a poly-silicon film, and forming a second gate stack including a second gate insulating film and a second gate electrode by patterning the second silicon oxide film, the high dielectric film, the metal film, and the second poly-silicon film pattern in the core/peripheral region, wherein the second gate insulating film includes a silicon oxide film and a high dielectric film, and the second gate electrode includes a metal film and a poly-silicon film.

The first poly-silicon film pattern of the cell region may be formed by forming the first poly-silicon film doped with impurities on the first silicon oxide film in the cell region and in the core/peripheral region, and etching the first poly-silicon film to have a step portion between the cell region and the core/peripheral region.

The method may further include forming a protection film on a top surface and a side wall of the first poly-silicon film pattern in the cell region for preventing the impurities included in the first poly-silicon film from being diffused after forming the first poly-silicon film pattern in the cell region.

Forming the second silicon oxide film, the high dielectric film, the metal film, and the second poly-silicon film pattern in the core/peripheral region may include sequentially forming the high dielectric film, the metal layer, and a second poly-silicon film on the protection film in the cell region and on the silicon oxide film in the core/peripheral region, planarizing the second poly-silicon film to expose the metal layer in the cell region, and etching the protection film, the high dielectric film, and the metal film to have the second poly-silicon film only in the core/peripheral region.

The method may further include forming a third gate stack including a third gate insulating film and a third gate electrode on the semiconductor substrate in the core/peripheral region, wherein the third gate insulating film may include a silicon oxide film and the third gate electrode may include a poly-silicon film.

The third gate insulating film may have a thickness that is substantially the same as a thickness of the first gate insulating film.

The semiconductor substrate of the cell region may include trenches, the first gate insulating film, and the first gate electrode, wherein the first gate insulating film may include a silicon oxide film and is on inner walls and on a bottom surface of the trenches, and the first gate electrode may be in the trenches and projected above the semiconductor substrate.

The high dielectric film may include at least one of a HfO₂ film, a ZrO₂ film, a TiO₂ film, a Al₂O₃ film, a Ta₂O₃ film, a Nb₂O₃ film, a Pr₂O₃ film, a Ce₂O₃ film, a Dy₂O₃ film, a Er₂O₃ film, a Y₂O₃ film, a ZrSiO₄ film, a ZrSiON film, a HfSiO film, a HfSiON film, a HfAION film, a AlSiON film, a BaSiO₄ film, a PbSiO₄ film, a BST film, and a PZT film.

The metal film may include at least one of a Ta film, a Ti film, a Al film, a Ag film, a Cu film, a Hf film, a Zr film, a Mn film, a Ni film, a Pd film, a Pt film, a Be film, a Ir film, a Te film, a Re film, a Ru film, a RuO₂ film, a TiN film, a TaN film, a WN film, a HfN film, a ZrN film, a TaSiN film, a TiSiN film, a NiSi film, and a metal silicide film.

The integrated circuit semiconductor device may be a dynamic random access memory (DRAM) semiconductor device.

The first gate stack and the second gate stack may be simultaneously formed through one photoetching.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic layout of an integrated circuit semiconductor device according to an embodiment;

FIG. 2 illustrates a cross sectional view of an integrated circuit semiconductor device according to another embodiment;

FIG. 3 illustrates a cross sectional view of an integrated circuit semiconductor device according to another embodiment;

FIGS. 4 through 12 illustrate cross sectional views of stages in a method of manufacturing the integrated circuit semiconductor device of FIG. 2;

FIG. 13 illustrates a plan view of a memory module using a chip according to an embodiment; and

FIG. 14 illustrates a block diagram of an electronic system using a chip according to an embodiment.

### DETAILED DESCRIPTION

Korean Patent Application No. 10-2008-0090685, filed on Sep. 16 2008, in the Korean Intellectual Property Office, and entitled: “Integrated Circuit Semiconductor Device Having Different Gate Stacks Between Cell Region and Core/Peripheral Region and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

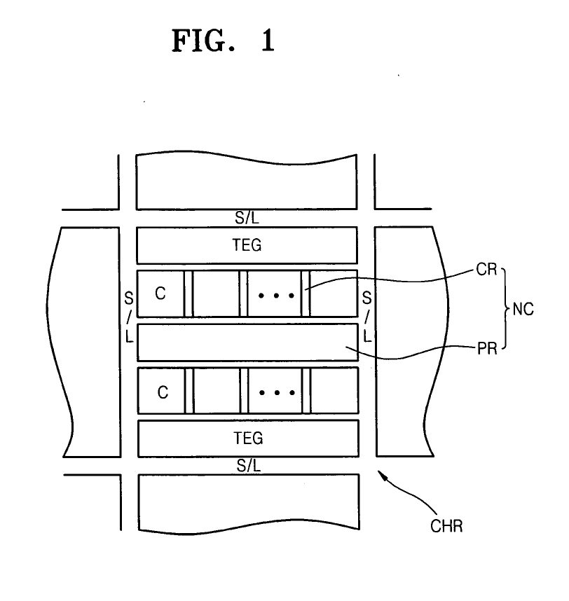

FIG. 1 illustrates a schematic layout of an integrated circuit semiconductor device according to an embodiment. More specifically, a chip region CHR, including a plurality of cell regions C, core regions CR, and peripheral regions PR, may be on a semiconductor substrate (semiconductor wafer), e.g., a silicon substrate. Each cell region C, core region CR, and peripheral region PR may include a plurality of unit cells (not illustrated). The chip region CHR may be partitioned by scribe line regions S/L. The scribe line regions S/L may partition the chip region CHR in both horizontal and vertical directions. The plurality of cell regions C may be formed in a horizontal direction with the core regions CR interposing between the adjacent cell regions C. The plurality of cell regions C may be formed in a stripe. An additional stripe of the plurality of cell regions C with the core regions CR interposing between the adjacent cell regions C may be formed parallel to the other plurality of cell regions C. The peripheral region PR may be between the two stripes of cell regions C. Test element groups TEG may be formed above and below the cell regions C in a vertical direction. In other words, test element groups TEG may sandwich two stripes of cell regions C which surround the peripheral region PR in the chip region CHR.

The layout of the integrated circuit semiconductor device of the embodiment is not limited to FIG. 1, and may be changed in various ways. The integrated circuit semiconductor device according to the embodiments may be formed of the cell regions C and the core/peripheral regions CR and PR, driving MOS transistors in the cell regions C. Hereinafter, the core/peripheral regions CR and PR may be referred to as NC.

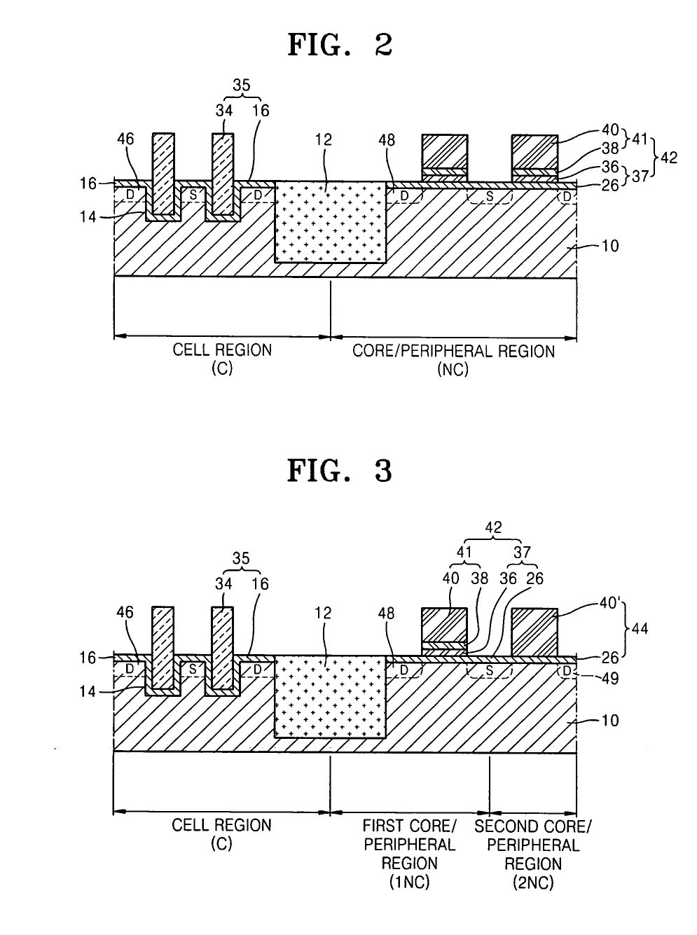

FIG. 2 illustrates a cross sectional view of an integrated circuit semiconductor device according to another embodiment. More specifically, the integrated circuit semiconductor device according to the current embodiment may include a semiconductor substrate 10, which has the cell region C and the core/peripheral region NC. The semiconductor substrate 10 may be a silicon substrate. The cell region C and the core/peripheral region NC may be isolated, e.g., insulated, from each other by a trench insulating film 12. Trenches 14 may be formed in the semiconductor substrate 10 of the cell region C. The trench insulating film 12 may be formed deeper into the semiconductor substrate 10 than the trenches 14. A first gate insulating film 16 formed of a silicon oxide film may be formed on inner walls and a bottom surface of the trenches 14. The first gate insulating film 16 may also be formed on first source/drain regions 46. The thickness of the first gate insulating film 16 formed on the inner walls and the bottom surface of the trenches 14 and the first gate insulating film 16 on the source/drain regions 46 may be substantially the same.

First gate electrodes 34, e.g., a poly-silicon film (poly-silicon film pattern) doped with impurities, may be formed on the first gate insulating films 16 disposed inside the trenches 14 in the cell region C. The first gate electrodes 34 may fill the trenches 14 and may project above the semiconductor substrate 10. The first gate electrode 34 may be formed of a poly-silicon film doped with N-type impurities, e.g., arsenic and/or phosphorus. In the cell region C, a first gate stack 35 may be formed of the first gate insulating film 16 and the first gate electrode 34. As described above, the first gate insulating film 16 may be formed of the silicon oxide film and the first gate electrode 34 may be formed of the poly-silicon film doped with impurities. The first source/drain region 46 may be formed on the both sides of the first gate stack 35 in the semiconductor substrate 10 of the cell region C. In FIG. 2, D denotes a drain region and S denotes a source region. The first gate stack 35 may share the drain region D and the source region S with the adjacent first gate stack 35.

Accordingly, a first MOS transistor, i.e., the first gate stack 35, including the first gate insulating film 16, the first gate electrode 34, and the first source/drain region 46 may be formed on the semiconductor substrate 10 of the cell region C. Since the first MOS transistor, i.e., the first gate stack 35, in the cell region C employs the first gate insulating film 16 formed of the silicon oxide film and the first gate electrode 34 formed of the poly-silicon film doped with impurities, problems of contamination by metal elements due to usage of a high dielectric film and problems in metal film etching for forming a metal gate may not occur.

In the semiconductor substrate 10 of the core/peripheral region NC, a second gate stack 42 formed of a silicon oxide film 26, a high dielectric film pattern 36 having a higher dielectric constant than that of the silicon oxide film 26, a metal film pattern 38, and a poly-silicon film pattern 40 doped with impurities may be formed. The high dielectric film pattern 36 may be formed of various kinds of films. For example, the high dielectric film pattern 36 may be formed of at least one of a HfO₂ film, a ZrO₂ film, a TiO₂ film, a Al₂O₃ film, a Ta₂O₃ film, a Nb₂O₃ film, a Pr₂O₃ film, a Ce₂O₃ film, a Dy₂O₃ film, a Er₂O₃ film, a Y₂O₃ film, a ZrSiO₄ film, a ZrSiON film, a HfSiO film, a HfSiON film, a HfAlON film, a AlSiON film, a BaSiO₄ film, a PbSiO₄ film, a BST(BaSrTiO₃) film, and a PZT(Pb(ZrₓTi₁₋ₓ)O₃) film.

The metal film pattern 38 may be formed of various kinds of films. For example, the metal film pattern 38 may be formed of at least one of a Ta film, a Ti film, an Al film, a Ag film, a Cu film, a Hf film, a Zr film, a Mn film, a Ni film, a Pd film, a Pt film, a Be film, an Ir film, a Te film, a Re film, a Ru film, a RuO₂ film, a TiN film, a TaN film, a WN film, a HfN film, a ZrN film, a TaSiN film, a TiSiN film, a NiSi film, and a metal silicide film.

The silicon oxide film 26 and the high dielectric film pattern 36 together may form a second gate insulating film 37 in the core/peripheral region NC. In another implementation, the second gate insulating film 37 may not include the silicon oxide film 26. The metal film pattern 38 and the poly-silicon film pattern 40 together may form a second gate electrode 41. In another implementation, the second gate electrode 41 may not include the poly-silicon film pattern 40. A second source/drain region 48 may be formed on the both sides of the second gate stack 42 on the semiconductor substrate 10 of the core/peripheral region (NC). Each second gate stack 42 may share the drain region D and the source region S with the adjacent second gate stack 42.

Accordingly, a second MOS transistor, i.e., the second gate stack 42, including the second gate insulating film 37 and the second gate electrode 41, and the second source/drain region 48 may be formed on the semiconductor substrate 10 of the core/peripheral region NC. As for a gate insulating film of a MOS transistor used in an integrated circuit semiconductor device, a silicon oxide film may be mainly used since a thickness of the silicon oxide film may be easily controlled and interfacial properties between the silicon oxide film and silicon is excellent. The thickness of the silicon oxide film, used as the gate insulating film, may gradually become thinner for high integration of the semiconductor device and for reducing short channel effect. If the thickness of the silicon oxide film is thin, however, a leakage current of the MOS transistor may be increased. Accordingly, the high dielectric film pattern 36 having a higher dielectric constant than that of the silicon oxide film may be used as the gate insulating film forming the second gate stack 42 as the MOS transistor in the present embodiment. Since the second MOS transistor, i.e., the second gate stack 42, of the core/peripheral region NC includes the high dielectric film pattern 36, a leakage current may be prevented from being increased.

In addition, as a thickness of the gate insulating film decreases in the integrated circuit semiconductor device, a poly-gate depletion effect may occur in a poly-silicon film for gate electrodes in the MOS transistor. A poly-silicon depletion layer generated due to the poly-gate depletion effect may increase an electronic equivalent oxide thickness of the gate insulating film, thereby decreasing a driving current of the MOS transistor. Accordingly, a metal gate electrode, e.g., the second gate electrode 41, may be used as a gate electrode forming the gate stack in the MOS transistor according to the embodiments. Since the second MOS transistor of the core/peripheral region NC includes the metal film pattern 38, poly-gate depletion may be improved, thereby improving performance of the second MOS transistor.

The gate insulating films and the gate electrodes forming the gate stacks of the MOS transistor, however, may be formed differently in each region, i.e., the cell region and the core/peripheral region, in the integrated circuit semiconductor device based on the following reasons.

The degree of integration and the pattern density may be high in the cell region of the integrated circuit semiconductor device. Also, a recess channel array transistor may be employed to the cell region of the integrated circuit semiconductor device, e.g., a dynamic random access memory (DRAM) semiconductor device. If the high dielectric film and the metal gate electrode are employed in the cell region of the integration circuit semiconductor device, a metal element forming the high dielectric film or the metal gate electrode may be diffused into a semiconductor substrate, i.e., a silicon substrate, during heat treatment, and thus, the silicon substrate may be contaminated. If the semiconductor substrate is contaminated by the metal element, a leakage current may increase. In particular, refresh characteristics may decrease in the integrated circuit semiconductor device, e.g., DRAM semiconductor device.

In addition, to employ the metal gate electrode as a gate electrode of the recess channel array transistor of the integrated circuit semiconductor device, e.g., DRAM semiconductor device, a metal layer may be patterned. Photoetching of the metal layer may be hard, however, since the photoetching may form a metal layer pattern being formed only on the inner wall and the bottom of a trench in the recess channel array transistor. Therefore, an electric short circuit may occur when contact between the metal gate electrode and source/drain electrodes is made. Accordingly, the gate insulating film and the gate electrode forming the gate stack in the cell region may employ the silicon oxide film and the poly-silicon film doped with impurities, respectively, in the integrated circuit semiconductor device.

The degree of integration and the pattern density may be lower in the core/peripheral region than the cell region in the integrated circuit semiconductor device. In addition, the recess channel array transistor may not be employed in the core/peripheral region of the DRAM semiconductor device. Accordingly, the high dielectric film having a higher dielectric constant than that of the silicon oxide film may be employed as the gate insulating film forming the gate stack in the core/peripheral region of the integrated circuit semiconductor device. Also, the metal gate electrode preventing poly-silicon depletion may be employed as the gate electrode in the core/peripheral region, thereby improving performance of the MOS transistor.

As the integrated circuit semiconductor device is highly integrated, efficiency of the MOS transistors included in the integrated circuit semiconductor device may become low. For example, as the integrated circuit semiconductor device is highly integrated, a gate insulating film may become thinner. Further, a high degree of integration may result in short channel effects, increased a leakage current, and a low driving current due to depletion of gate electrodes. Therefore, there is a need of improving efficiency of the MOS transistors formed in the integrated circuit semiconductor device. Also, efficiency of the MOS transistors formed in the cell region and the core/peripheral region should be separately controlled.

In the integrated circuit semiconductor device according to embodiments, the gate insulating films and the gate electrodes forming the gate stacks of the MOS transistor may be formed differently in each region, i.e., the cell region and the core/peripheral region. Thus, performance of the MOS transistor in the cell region may be prevented from decreasing and the performance of the MOS transistor in the core/peripheral region may improve.

FIG. 3 illustrates a cross sectional view of an integrated circuit semiconductor device according to another embodiment. More specifically, the integrated circuit semiconductor device according to the current embodiment may be substantially the same as the integrated circuit semiconductor device of FIG. 2, except for the core/peripheral region NC in FIG. 3 being divided into a first core/peripheral region 1NC and a second core/peripheral region 2NC.

The first core/peripheral region 1NC may include the second gate stack 42 formed of the second gate insulating film 37 and the second gate electrode 41 on the semiconductor substrate 10, as in the core/peripheral region NC illustrated in FIG. 2. The second gate insulating film 37 may include the silicon oxide film 26 and the high dielectric film pattern 36, and the second gate electrode 41 may include the metal film pattern 38 and the poly-silicon film pattern 40. The second core/peripheral region 2NC may include a third gate stack 44 including a gate insulating film, e.g., the second gate insulating film 26, and a third gate electrode 40′ on the semiconductor substrate 10. The second gate insulating film 26 may be formed of a silicon oxide film, and the third gate electrode 40′ may be formed of a poly-silicon film pattern doped with impurities, e.g., N-type impurities. The second gate insulating film 26 may have substantially the same thickness as the first gate insulating film 16. A third source/drain region 49 may be formed on the both sides of the third gate stack 44 on the semiconductor substrate 10. The second gate stack 42 and the third gate stack 44 may share the source region S.

In the current embodiment, the second core/peripheral region 2NC having the third gate stack 44 may be further included, in addition to the first core/peripheral region 1NC in core/peripheral region (NC). The second gate insulating film 26 may be formed of the silicon oxide film and may have substantially the same thickness as the first gate insulating film 16. The third gate electrode 40′ may be formed of the poly-silicon film pattern doped with impurities. Accordingly, in the current embodiment, the first core/peripheral region 1NC and the second core/peripheral region 2NC may be included. Also, the structures of the second and third gate stacks 42 and 44, and thicknesses of the second gate insulating films 37 and 26 may vary so that various forms of the MOS transistor required in the core/peripheral region NC may be realized.

The third gate stack 44 formed of the second gate insulating film 26 and the third gate electrode 40′ in the second core/peripheral region 2NC may be manufactured in the same manner as the first gate stack 35 on the semiconductor substrate 10 in the cell region C. The third gate stack 44 formed on the semiconductor substrate 10 may be include the second gate insulating film 26 formed of the silicon oxide film and the third gate electrode 40′ formed of the poly-silicon film doped with impurities.

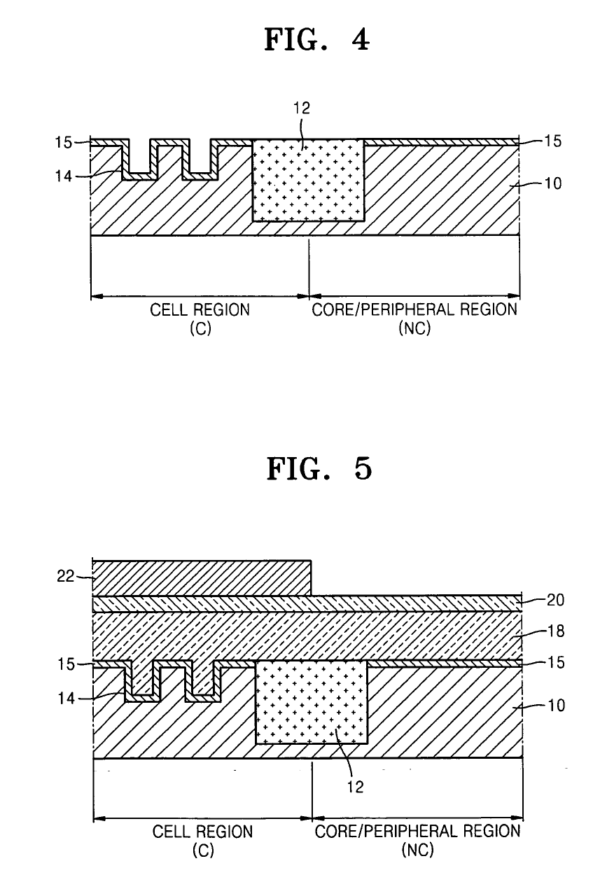

FIGS. 4 through 12 illustrate cross sectional views of stages in a method of manufacturing the integrated circuit semiconductor device of FIG. 2. Referring to FIG. 4, the semiconductor substrate 10, e.g., a silicon substrate, may be defined by the cell region C and the core/peripheral region NC. The cell region C and the core/peripheral region NC may be isolated from each other by the trench insulating film 12. The trenches 14 may be formed in the cell region C and the first gate insulating film 16, e.g., a first silicon oxide film 16, may be formed on the inner walls and the bottom surface of the trenches 14. The first silicon oxide film 16 may also be formed on the semiconductor substrate 10 between the adjacent trenches 14. The first silicon oxide film 16 may also be formed on the semiconductor substrate 10 in the core/peripheral region NC.

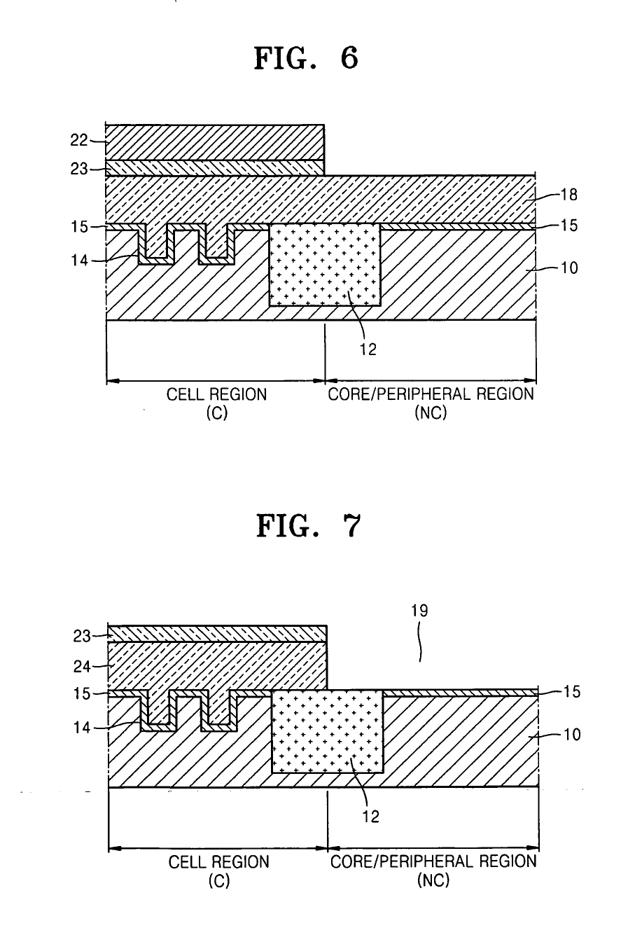

Referring to FIGS. 5 and 6, a first poly-silicon film 18 doped with impurities, e.g., N-type impurities, may be formed on the first silicon oxide film 16 disposed in the cell region C and in the core/peripheral region NC. The first poly-silicon film 18 may fill trenches 14 in the cell region C. A mask layer 20 may be formed on the first poly-silicon film 18 in both the cell region C and the core/peripheral region NC. The mask layer 20 may be a silicon oxide film. A photoresist pattern 22 may be formed on the mask layer 20. The photoresist pattern 22 may only be formed in the cell region C.

As illustrated in FIG. 6, the mask layer 20 may be dry etched using the photoresist pattern 22 as a mask, thereby forming a mask pattern 23. The mask pattern 23 may be also formed only in the cell region C. The mask layer 20 in the core/peripheral region (NC) may be removed.

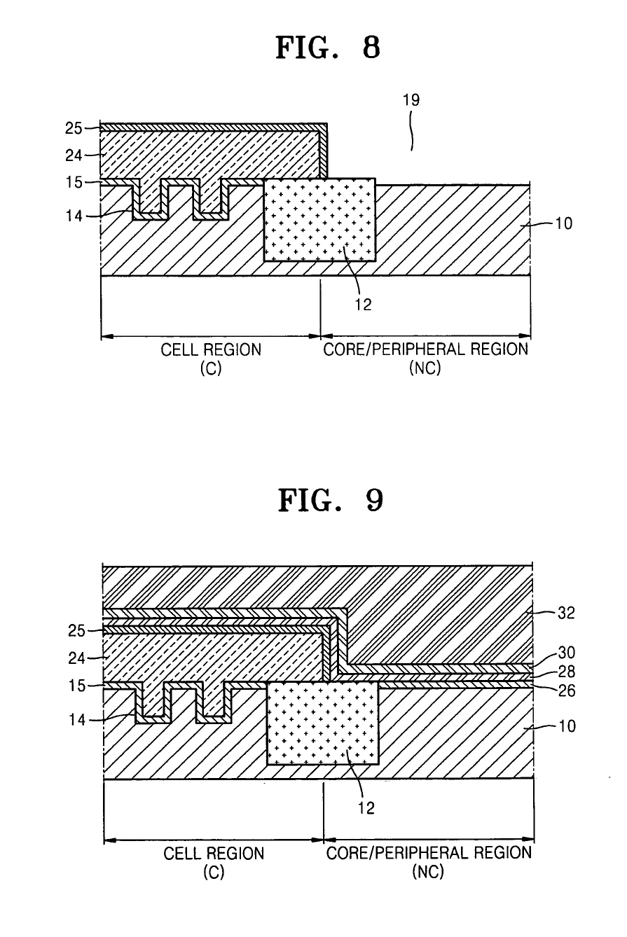

Referring to FIGS. 7 and 8, after the photoresist pattern 22 is removed, the first poly-silicon film 18 may be etched using the mask pattern 23 as a mask, thereby forming a first poly-silicon film pattern 24. The first poly-silicon film pattern 24 may be only formed in the cell region C so that a step portion 19 may be generated between the cell region C and the core/peripheral region NC.

After the mask pattern 23 is removed, a protection film 25 may be formed on the top surface and on the side wall of the first poly-silicon film pattern 24 in the cell region C, as illustrated in FIG. 8. In detail, an insulating film may be formed on the part of the semiconductor substrate 10 on which the first poly-silicon film pattern 24 is formed, and then the insulating film may be etched to form the protection film 25. The protection film 25 may prevent the impurities included in the first poly-silicon film pattern 24 from being diffused to outside. The protection film 25 may be a silicon oxide film.

While forming the protection film 25, the first silicon oxide film 16 formed in the core/peripheral region NC may be removed, leaving the first silicon oxide film 16 only in the cell region C. In FIGS. 7 and 8, the protection film 25 may be formed after the mask pattern 23 is removed. Alternatively, the protection film 25 may be formed without removing the mask pattern 23.

Referring to FIG. 9, a second silicon oxide film 26 may be formed in the core/peripheral region NC. The second silicon oxide film 26 may be formed on the semiconductor substrate 10 of the core/peripheral region (NC), but may not be formed on the trench insulating film 12. A high dielectric film 28 having a higher dielectric constant than that of the second silicon oxide film 26, a metal layer 30, and a second poly-silicon film 32 doped with impurities may be sequentially formed on the whole surface of the cell region C and on the core/peripheral region NC. In other words, the high dielectric film 28, the metal layer 30, and the second poly-silicon film 32 may be sequentially formed on the protection film 25 in the cell region C and on the silicon oxide film 26 in the core/peripheral region NC as well as on the trench insulating film 12 in the core/peripheral region. The high dielectric film 28, the metal layer 30, and the second poly-silicon film 32 may be continuous layers extending from the cell region (C) to the core/peripheral region (NC). The step portion 19 in the core/peripheral region NC may be filled with the second poly-silicon film 32. In other words, the second poly-silicon film 32 in the cell region (C) and the core/peripheral region (NC) may reach a same height, not withstanding a difference in a depth.

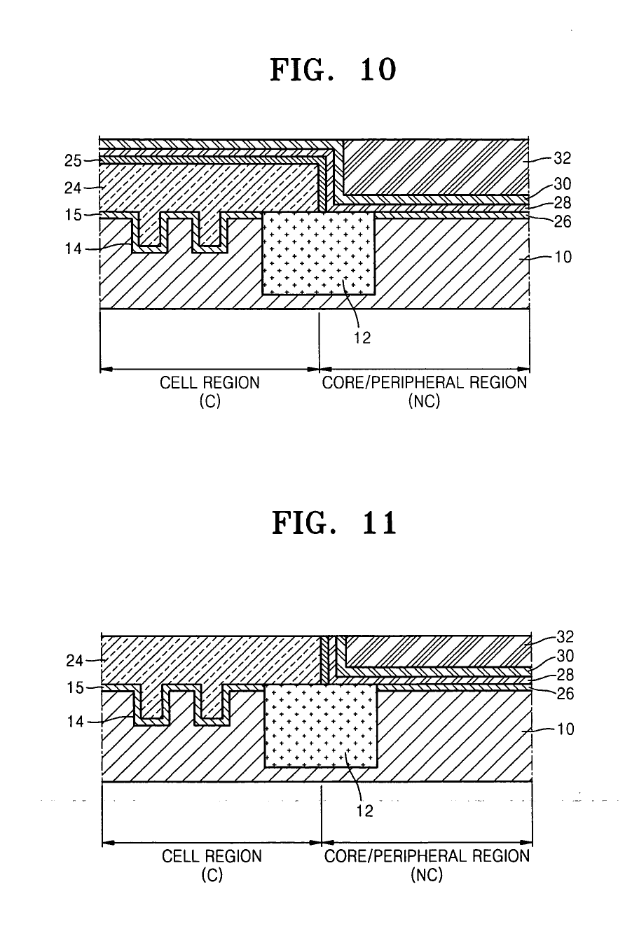

Referring to FIGS. 10 and 11, the second poly-silicon film 32 disposed in the cell region C and the core/peripheral region NC may be planarized to expose the metal layer 30 in the cell region C. Then, as illustrated in FIG. 11, the metal layer 30, the high dielectric film 28, and the protection film 25 in the cell region (C) may be removed by wet etching or dry etching. Accordingly, the first silicon oxide film 16 and the first poly-silicon film pattern 24 may only remain in the cell region C. In the core/peripheral region (NC), however, the second silicon oxide film 26, the high dielectric film 28, the metal layer 30, and the second poly-silicon film 32 may remain.

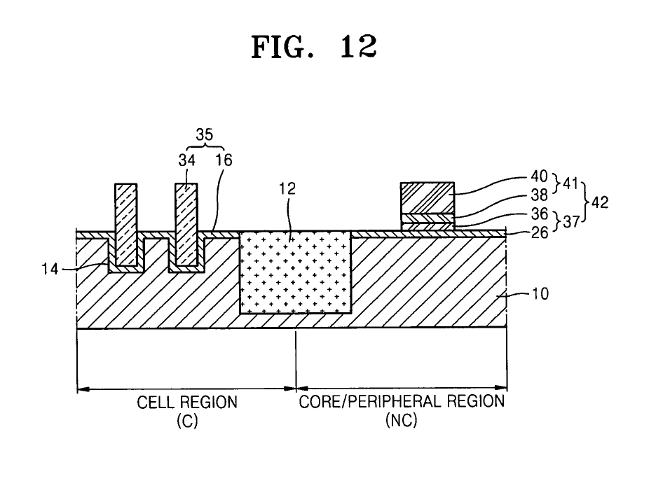

Referring to FIG. 12, the first poly-silicon film pattern 24 of the cell region C may be patterned by photoetching to form the first gate electrode 34. In the process, portions of the first poly-silicon film pattern 24 on the first silicon oxide film 16 and on the trench insulating film 12 may be removed. In the cell region C, the first silicon oxide film 16 may form the first gate insulating film 16. As described above, the cell region C may include the first gate stack 35 formed of the first gate insulating film 16 and the first gate electrode 34, wherein the first gate insulating film 16 may be formed of the silicon oxide film and the first gate electrode 34 may be formed of the poly-silicon film doped with impurities.

The second poly-silicon film 32, the metal layer 30, and the high dielectric film 28 may be patterned by photoetching to form the second gate stack 42 including the high dielectric film pattern 36 having a higher dielectric constant than that of the silicon oxide film 26, the metal film pattern 38, and the poly-silicon film pattern 40 doped with impurities. The silicon oxide film 26 and the high dielectric film pattern 36 may form the second gate insulating film 37. The metal film pattern 38 and the poly-silicon film pattern 40 may form the second gate electrode 41. The second gate insulating film 37 and the second gate electrode 41 together may form the second gate stack 42.

The first gate insulating film 16 and the first gate electrode 34, i.e., the first gate stack 35, in the cell region C, and the high dielectric film pattern 36, the metal film pattern 38, and the poly-silicon film pattern 40 doped with impurities, i.e., the second gate stack 42, in the core/peripheral region NC may be simultaneously formed by one photoetching process.

Then, as illustrated in FIG. 2, the first source/drain region 46 may be formed on the both sides of the first gate stack 35 on the semiconductor substrate 10 of the cell region C. The second source/drain region 48 may be formed on the both sides of the second gate stack 42 on the semiconductor substrate 10 of the core/peripheral region NC.

Hereinafter, various applications using the integrated circuit semiconductor device according to the embodiments may be described. If the integrated circuit semiconductor device is packaged, a chip, e.g., semiconductor chip, may be manufactured. The following may be a few applications of the chip.

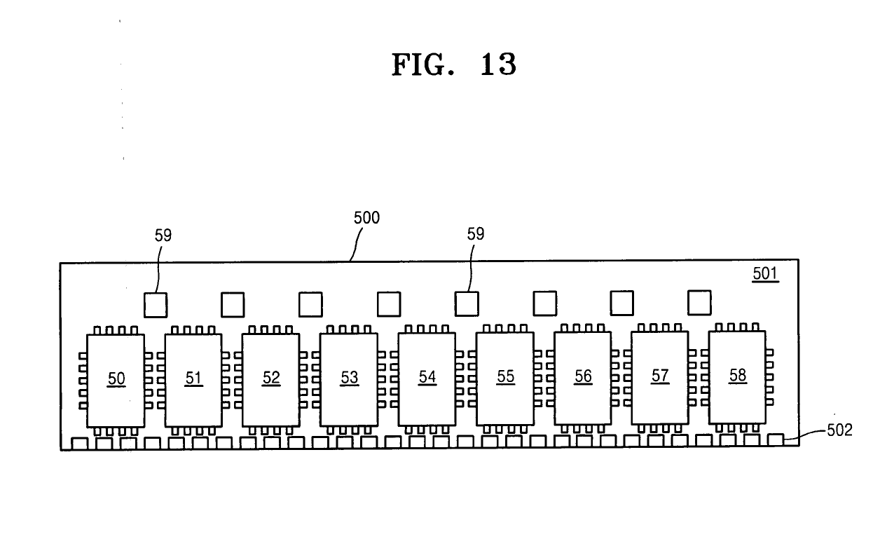

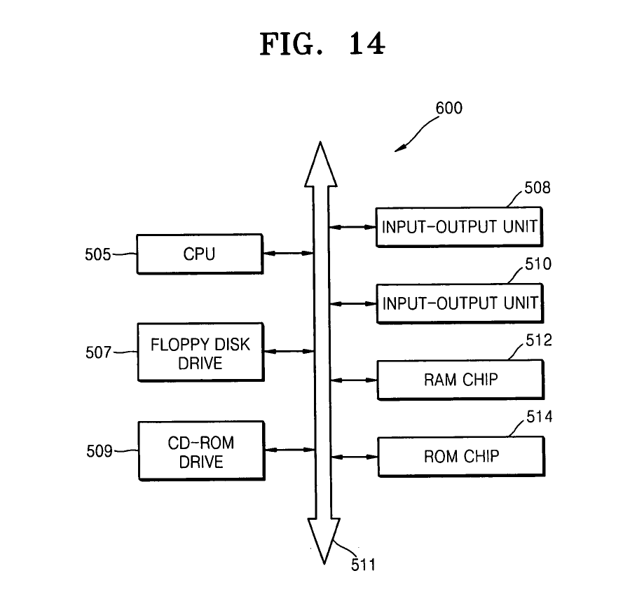

FIG. 13 illustrates a plan view of a memory module using the chip. More specifically, chips 50-58 may be respectively packaged integrated circuit semiconductor devices according to the embodiments. When the integrated circuit semiconductor devices are DRAM devices and are packaged, DRAM chips may be manufactured. These chips 50-58, e.g., DRAM chips, may be employed in a memory module 500. The memory module 500 may include a module substrate 501 on which the chips 50-58 may be attached. In the memory module 500, connection parts 502 to be fixed with sockets of a motherboard may be disposed on one side, e.g., on a bottom side, of the module substrate 501 and ceramic decoupling capacitors 59 may be disposed on the other side, e.g., on a top side, of the module substrate 501. The memory module 500 according to the current embodiment may not be limited to FIG. 12, and may be manufactured in various forms.

FIG. 14 illustrates a block diagram of an electronic system 600 using the chips. More specifically, the electronic system 600 according to the current embodiment may denote a computer. The electronic system 600 may include peripheral devices, e.g., a central processing unit (CPU) 505, a floppy disk drive 507, and a CD-ROM drive 509, and input-output units 508, a random access memory (RAM) chip 512, and a read only memory (ROM) chip 514. A control signal or data may be transmitted between the elements above using a communication channel 511.

The integrated circuit semiconductor device according to the embodiments may be packaged and the RAM chip 512 may be employed in the electronic system 600 as illustrated in FIG. 14. The RAM chip 512 may be a DRAM chip. The RAM chip 512 of FIG. 14 may be replaced with the memory module 500 including the chips 50 as illustrated in FIG. 13.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An integrated circuit semiconductor device, comprising:
a semiconductor substrate having a cell region and a core/peripheral region;
a first gate stack including a first gate insulating film and a first gate electrode on the semiconductor substrate in the cell region, wherein the first gate insulating film includes a silicon oxide film and the first gate electrode includes a poly-silicon film doped with impurities; and
a second gate stack including a second gate insulating film and a second gate electrode on the semiconductor substrate in the core/peripheral region, wherein the second gate insulating film includes a high dielectric film having a higher dielectric constant than that of the silicon oxide film and the second gate electrode includes a metal film.

2. The device as claimed in claim 1, wherein the integrated circuit semiconductor device is a dynamic random access memory (DRAM) semiconductor device.

3. The device as claimed in claim 1, further comprising a third gate stack including a third gate insulating film and a third gate electrode on the semiconductor substrate in the core/peripheral region, wherein the third gate insulating film includes a silicon oxide film and the third gate electrode includes a poly-silicon film doped with impurities.

4. The device as claimed in claim 3, wherein the third gate insulating film has a thickness substantially the same as a thickness of the first gate insulating film.

5. The device as claimed in claim 1, wherein:
the second gate insulating film includes a silicon oxide film and the high dielectric film, and
the high dielectric film is on the silicon oxide film on the semiconductor substrate.

6. The device as claimed in claim 1, wherein:
the second gate electrode includes a poly-silicon film and the metal film, and
the poly-silicon film is doped with impurities and is on the metal film.

7. An integrated circuit semiconductor device, comprising:
a semiconductor substrate having a cell region and a core/peripheral region;
trenches in the semiconductor substrate in the cell region;
a first gate stack in the cell region, the first gate stack including a silicon oxide film on inner walls and a bottom surface of the trenches and a poly-silicon film doped with impurities on the silicon oxide film in the trenches and projected above the semiconductor substrate; and
a second gate stack in the core/peripheral region, the second gate stack sequentially including a silicon oxide film, a high dielectric film having a higher dielectric constant than that of the silicon oxide film, a metal film, and a poly-silicon film on the semiconductor substrate.

8. The device as claimed in claim 7, further comprising a third gate stack including a silicon oxide film and a poly-silicon film on the semiconductor substrate in the core/peripheral region, wherein the poly-silicon film is doped with impurities.

9. The device as claimed in claim 8, wherein the silicon oxide film of the third gate stack has a thickness that is substantially the same as a thickness of the silicon oxide film of the first gate stack.

10. A method of manufacturing an integrated circuit semiconductor device, the method comprising:
providing a semiconductor substrate;
sequentially forming a first silicon oxide film and a first poly-silicon film pattern doped with impurities on the semiconductor substrate in a cell region of the semiconductor substrate;
sequentially forming a second silicon oxide film, a high dielectric film having a higher dielectric constant than that of the second silicon oxide film, a metal film, and a second poly-silicon film pattern on the semiconductor substrate in a core/peripheral region of the semiconductor substrate;
forming a first gate stack including a first gate insulating film and a first gate electrode by patterning the first silicon oxide film and the first poly-silicon film pattern in the cell region, wherein the first gate insulating film includes a silicon oxide film and a first gate electrode includes a poly-silicon film; and
forming a second gate stack including a second gate insulating film and a second gate electrode by patterning the second silicon oxide film, the high dielectric film, the metal film, and the second poly-silicon film pattern in the core/peripheral region, wherein the second gate insulating film includes a silicon oxide film and a high dielectric film, and the second gate electrode includes a metal film and a poly-silicon film.

11. The method as claimed in claim 10, wherein forming the first poly-silicon film pattern of the cell region includes:
forming the first poly-silicon film doped with impurities on the first silicon oxide film in the cell region and in the core/peripheral region; and
etching the first poly-silicon film to have a step portion between the cell region and the core/peripheral region.

12. The method as claimed in claim 11, further comprising forming a protection film on a top surface and a side wall of the first poly-silicon film pattern in the cell region for preventing the impurities included in the first poly-silicon film from being diffused after forming the first poly-silicon film pattern in the cell region.

13. The method as claimed in claim 12, wherein forming the second silicon oxide film, the high dielectric film, the metal film, and the second poly-silicon film pattern in the core/peripheral region includes:
sequentially forming the high dielectric film, the metal layer, and a second poly-silicon film on the protection film in the cell region and on the silicon oxide film in the core/peripheral region;
planarizing the second poly-silicon film to expose the metal layer in the cell region; and
etching the protection film, the high dielectric film, and the metal film to have the second poly-silicon film only in the core/peripheral region.

14. The method as claimed in claim 11, further comprising forming a third gate stack including a third gate insulating film and a third gate electrode on the semiconductor substrate of the core/peripheral region, wherein the third gate insulating film includes a silicon oxide film and the third gate electrode includes a poly-silicon film.

15. The method as claimed in claim 14, wherein the third gate insulating film has a thickness that is substantially the same as a thickness of the first gate insulating film.

16. The method as claimed in claim 11, wherein the semiconductor substrate of the cell region includes trenches, the first gate insulating film, and the first gate electrode, wherein the first gate insulating film includes a silicon oxide film and is on inner walls and on a bottom surface of the trenches, and the first gate electrode is in the trenches and projected above the semiconductor substrate.

17. The method as claimed in claim 11, wherein the high dielectric film includes at least one of a HfO₂ film, a ZrO₂ film, a TiO₂ film, a Al₂O₃ film, a Ta₂O₃ film, a Nb₂O₃ film, a Pr₂O₃ film, a Ce₂O₃ film, a Dy₂O₃ film, a Er₂O₃ film, a Y₂O₃ film, a ZrSiO₄ film, a ZrSiON film, a HfSiO film, a HfSiON film, a HfAlON film, a AlSiON film, a BaSiO₄ film, a PbSiO₄ film, a BST film, and a PZT film.

18. The method as claimed in claim 11, wherein the metal film includes at least one of a Ta film, a Ti film, a Al film, a Ag film, a Cu film, a Hf film, a Zr film, a Mn film, a Ni film, a Pd film, a Pt film, a Be film, a Ir film, a Te film, a Re film, a Ru film, a RuO₂ film, a TiN film, a TaN film, a WN film, a HfN film, a ZrN film, a TaSiN film, a TiSiN film, a NiSi film, and a metal silicide film.

19. The method as claimed in claim 11, wherein the integrated circuit semiconductor device is-a dynamic random access memory (DRAM) semiconductor device.

20. The method as claimed in claim 11, wherein the first gate stack and the second gate stack are simultaneously formed through one photoetching.
